(19) United States
(12) Patent Application Publication
(10) Pub. No.: US 2018/0246170 A1
(43) Pub. Date: Aug. 30, 2018

(54) ROBOTIC CIRCUIT ANALYZER TOOL

(71) Applicant: GM Global Technology Operations LLC, Detroit, MI (US)

(72) Inventor: Joseph L. Jablonski, Linden, MI (US)

(21) Appl. No.: 15/443,629

(22) Filed: Feb. 27, 2017

(51) Int. Cl. G01R 31/34; B25J 19/00; G01R 1/04

(52) U.S. Cl. CPC G01R 31/34; G01R 1/0416; B25J 19/0095

(57) ABSTRACT

A tool for providing an electrical interface between a motor circuit analyzer having a plurality of motor circuit analyzer connection ports and an electrically operated machine having electrical devices and a multi-conductor cable comprising electrical wires connected to the electrical devices. The tool includes a plurality of tool connection ports configured to be electrically connected to motor circuit analyzer connection ports. The tool also includes a plurality of terminals configured to be electrically connected to the conductors of the multi-conductor cable, and a switching section configured to selectively electrically connect two of the plurality of tool connection ports to two of the plurality of terminals.

### INTRODUCTION

The present disclosure generally relates to a tool and a method for interfacing a motor circuit analyzer tool to a robotic manipulator containing a plurality of motors, brakes, and position encoders.

The introductory description provided herein is for the purpose of generally presenting the context of the disclosure. Work of the presently named inventors, to the extent it is described in this introductory section, as well as aspects of the description that may not otherwise qualify as prior art at the time of filing, are neither expressly nor impliedly admitted as prior art against the present disclosure.

Robotic actuators used in manufacturing plants commonly are capable of movement about six or more axes, with each axis commonly having an associated motor, brake actuator, and position encoder. Electrical cables are used to convey power and signal information between a robotic controller and each motor, brake actuator, and position encoder. Each motor, each brake actuator, and each interconnecting electrical cable are subject to degradation over time, resulting in the need to replace motors, brake actuators, and cables over time to allow the robotic actuator to continue performing its intended function. Replacing such components and/or cables according to a preset schedule based on time and/or on a number of machine cycles may not be desirable, as it may result in unnecessary replacement of components and/or cables that have not experienced degradation sufficient to warrant replacement. Performing such replacements only after a component has failed is also undesirable due to the effects that unplanned downtime has on a manufacturing operation.

There is a desire for a tool that allows rapid identification of components in a robotic manipulator that have degraded to a point that service is called for.

### SUMMARY

According to several aspects, a tool is provided for providing an electrical interface between a motor circuit analyzer and a robotic manipulator. The motor circuit analyzer includes a plurality of motor circuit analyzer connection ports. The robotic manipulator includes a plurality of electrical devices and a multi-conductor cable containing electrical wires configured to electrically connect to the plurality of electrical devices. The tool includes a plurality of tool connection ports, each of which is configured to be electrically connected to one of the plurality of motor circuit analyzer connection ports. The tool further includes a plurality of terminals, each of which is configured to be electrically connected to one of the conductors of the multi-conductor cable. The tool also includes a switching section configured to selectively electrically connect a first tool connection port to a first terminal and to selectively electrically connect a second tool connection port to a second terminal.

In an additional aspect of the present disclosure, the plurality of electrical devices includes a plurality of electric motors.

In a further aspect of the present disclosure, the plurality of electrical devices includes a plurality of electrically actuated brakes.

In another aspect of the present disclosure, the plurality of electrical devices includes a plurality of electrically readable position sensors.

In an additional aspect of the present disclosure, the switching section is further configured to selectively electrically connect a third tool connection port to a third terminal.

In another aspect of the present disclosure, the motor circuit analyzer is configured to measure resistance, impedance, inductance, phase angle, dissipation factor, capacitance, and/or insulation resistance of a circuit that is electrically connected between two of the plurality of the motor circuit analyzer connection ports.

In a further aspect of the present disclosure, the multi-conductor cable is terminated in a first multi-pin connector, and the tool includes a second multi-pin connector that is configured to mate with the first multi-pin connector.

In an additional aspect of the present disclosure, each terminal is a pin in the second multi-pin connector.

In another aspect of the present disclosure, the switching section includes a plurality of sets of electrical contacts, wherein each set of contacts can selectively be placed in a closed state in which the contacts in the set of contacts are touching and able to conduct electricity therebetween and in an open state in which the contacts in the set of contacts are separated and unable to conduct electricity therebetween.

In a further aspect of the present disclosure, at least one of the plurality of sets of electrical contacts is a set of relay contacts whose opening and closing is controlled by current through a relay coil.

In an additional aspect of the present disclosure, the relay coil is configured to control opening and closing of a plurality of sets of electrical contacts.

In another aspect of the present disclosure, opening and closing of at least one of the plurality of sets of electrical contacts is controlled by a mechanically operated actuator.

According to several aspects, a method is provided for using a tool to analyze a robotic manipulator with a motor circuit analyzer. The motor circuit analyzer includes a plurality of motor circuit analyzer connection ports. The robotic manipulator includes a plurality of electrical devices and a multi-conductor cable having electrical wires configured to electrically connect to the plurality of electrical devices. The tool includes a plurality of tool connection ports, a plurality of terminals, and a switching section configured to selectively electrically connect a first tool connection port to a first terminal and to selectively electrically connect a second tool connection port to a second terminal. The method includes the steps of connecting a first tool connection port to a first motor circuit analyzer connection port and connecting a second tool connection port to a second motor circuit analyzer connection port. The method further includes the step of connecting the multi-conductor cable to the plurality of terminals. The method also includes the step of configuring the switches in the switching section to electrically connect the first motor circuit analyzer connection port and the second motor circuit analyzer connection port to one of the plurality of electrical devices. The method further includes the step of measuring an electrical property associated with the one of the plurality of electrical devices using the motor circuit analyzer.

In another aspect of the disclosure, the method further includes the step of comparing the measured value of the electrical property to a predetermined range.

In a further aspect of the disclosure, the predetermined range is based on a measurement taken at a previous time of the same electrical property associated with the same electrical device.

In another aspect of the disclosure, the method further includes the steps of disconnecting one of the plurality of electrical devices from the multi-conductor cable and connecting a circuit element having a known impedance to the multi-conductor cable in place of the disconnected device.

In a further aspect of the disclosure, the disconnected device is an electrically readable position sensor.

In another aspect of the disclosure, the electrical property is selected from the group consisting of resistance, impedance, inductance, phase angle, dissipation factor, capacitance, and insulation resistance.

In another aspect of the disclosure, the method further includes the steps of connecting a third tool connection port to a third motor circuit analyzer connection port, and configuring the switches in the switching section to electrically connect the third motor circuit analyzer connection port to one of the plurality of electrical devices.

### BRIEF DESCRIPTION OF THE DRAWINGS

The present disclosure will become more fully understood from the detailed description and the accompanying drawings, wherein:

FIG. 1 is a depiction of an interface tool connected to a motor circuit analyzer and to a robotic manipulator, according to an exemplary embodiment;

FIG. 2 is a schematic diagram of a first non-limiting exemplary embodiment of the interface tool;

FIG. 3 is a truth table describing the behavior of the embodiment of FIG. 2; and

FIG. 4 is a depiction of a second non-limiting exemplary embodiment of the interface tool.

### DETAILED DESCRIPTION

Terms such as “above”, “below”, “upward”, “downward”, “top”, “bottom”, “left”, “right”, etc., are used descriptively for the figures, and do not represent limitations on the scope of the invention as defined by the appended claims.

As used herein, a “motor circuit analyzer” (MCA) refers to a device that can be used to assess a degree of degradation of an electric motor, cable, or brake. This assessment is accomplished by detecting electrical imbalances in the circuit and by detecting degradation of electrical insulation. A motor circuit analyzer is generally configured to test for electrical resistance, impedance and/or inductance, phase angle, and insulation resistance. A motor circuit analyzer generally includes provision for three input/output connections to electrically connect to three phase windings of a motor, plus a fourth connection to circuit ground.

As used herein, the term “wire” is not limited to metal that has been drawn into a strand or rod, but rather may include any electrically conductive means known in the art including but not limited to conductor traces on a circuit board.

In the description of switches contained herein, the terms “pole” and “throw” are used to describe switch contact variations. As used herein, the number of “poles” is the number of electrically separate switches which are controlled by a single physical actuator. For example, a “triple-pole” switch has three separate sets of contacts that open and close in unison via the same mechanism. The number of “throws” is the number of separate wiring path choices that the switch can adopt for each pole. Each pole of a double-throw switch has a contact, referred to herein as a “common contact”, that can be connected to either of two other contacts, referred to herein as “output contacts”. Each pole of a triple-throw switch has a common contact which can be connected to one of three output contacts. When a switch is said to be in a given position (e.g. first position, second position), it is meant that the actuator for that switch is in the given position.

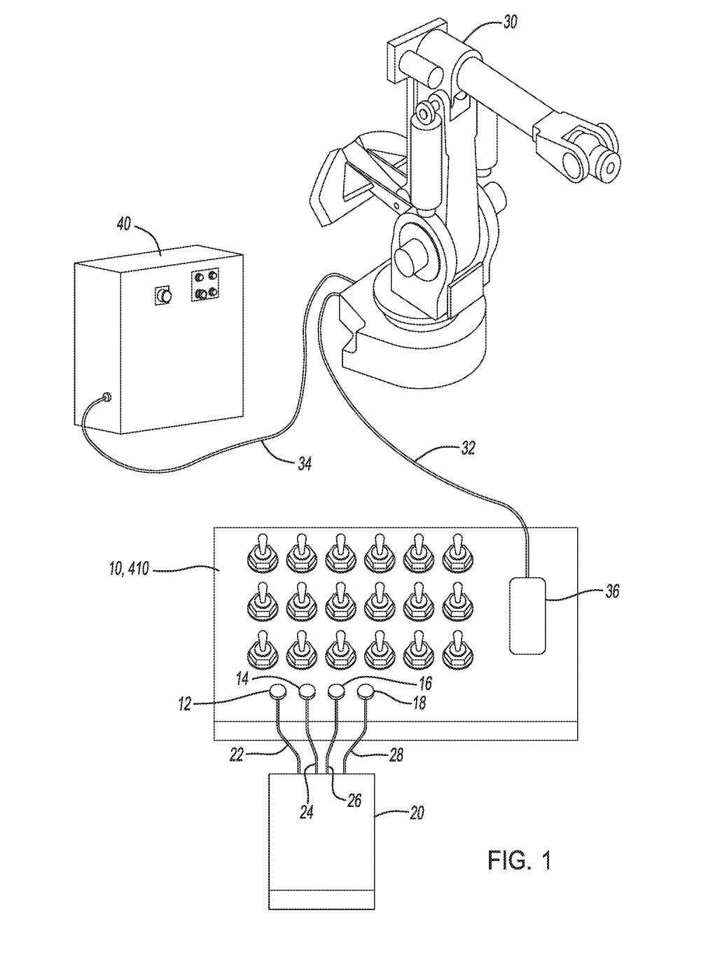

FIG. 1 is a depiction of a tool 10 configured to provide an electrical interface between an exemplary motor circuit analyzer 20 and an exemplary robotic manipulator 30. In the exemplary embodiment of FIG. 1, a first electrical cable 32 and a second electrical cable 34 are connected to the robotic manipulator 30. In this exemplary embodiment, the first electrical cable 32 is a multi-conductor cable that includes wires connected to motor, brake actuator, and encoder circuits contained in the robotic manipulator 30. The first electrical cable 32 is terminated in a first multi-pin connector 36. In normal operation of the robotic manipulator 30, the first electrical cable 32 is connected to a robotic controller 40 by plugging the first multi-pin connector 36 into a mating connector on the robotic controller 40. In the exemplary embodiment depicted in FIG. 1 the second electrical cable 34 includes measurement signals and is connected to the robotic controller 40.

The configuration depicted in FIG. 1 is a diagnostic configuration in which the first multi-pin connector 36, rather than being plugged into the robotic controller 40, is instead plugged into a mating connector on the tool 10. The tool 10 is also shown as being connected to input/output ports on the motor circuit analyzer 20, with a first MCA connection port 22 connected to a first tool connection port 12, a second MCA connection port 24 connected to a second tool connection port 14, a third MCA connection port 26 connected to a third tool connection port 16, and an MCA ground connection port 28 connected to a tool ground connection port 18.

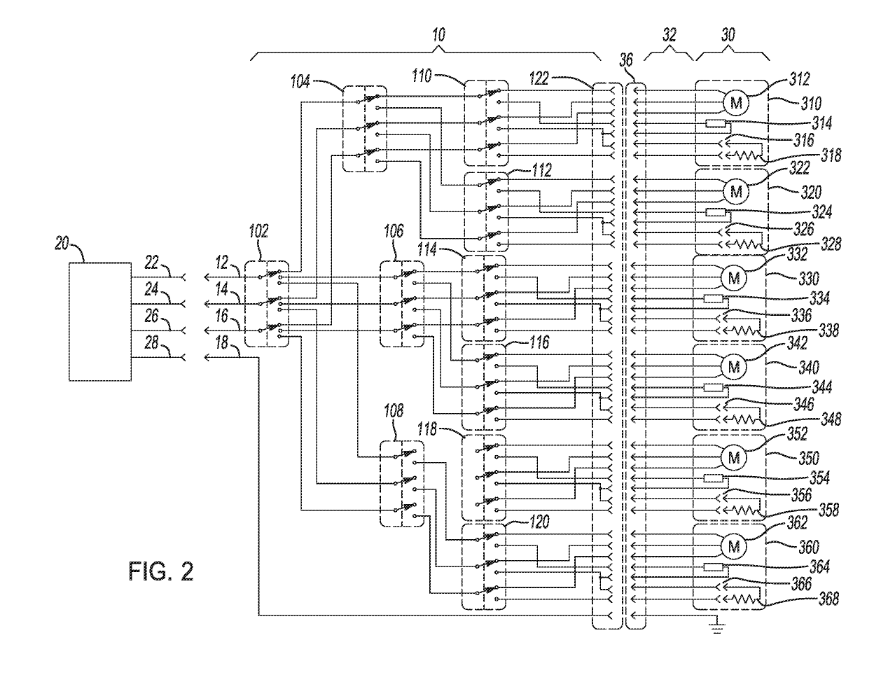

FIG. 2 is a schematic diagram of a first non-limiting exemplary embodiment of the interface tool 10, shown in relation to the motor circuit analyzer 20 and to the robotic manipulator 30. In FIG. 2 the robotic manipulator 30 is depicted as comprising six axes, with each axis having an associated motor, brake actuator, and position encoder. It will be appreciated that the interface tool 10 may be used in conjunction with a robotic manipulator 30 having fewer than six axes or with a robotic manipulator 30 having more than six axes without departing from the scope of the disclosure. In the depiction of FIG. 2, a first axis 310 of the robotic manipulator 30 is shown as including a first motor 312, a first brake actuator 314, and a first encoder connector 316 that is configured to mate with a first position encoder (not shown). FIG. 2 also shows a first resistor 318 that is configured to electrically interface with the first encoder connector 316, the use of which will be described later in this disclosure.

FIG. 2 also depicts a second axis 320 of the robotic manipulator 30 including a second motor 322, a second brake actuator 324, and a second encoder connector 326 that is configured to mate with a second position encoder (not shown). FIG. 2 also shows a second resistor 328 that is configured to electrically interface with the second encoder connector 326, the use of which will be described later in this disclosure.

FIG. 2 also depicts a third axis 330 of the robotic manipulator 30 including a third motor 332, a third brake actuator 334, and a third encoder connector 336 that is configured to mate with a third position encoder (not shown). FIG. 2 also shows a third resistor 338 that is configured to electrically interface with the third encoder connector 336, the use of which will be described later in this disclosure.

FIG. 2 also depicts a fourth axis 340 of the robotic manipulator 30 including a fourth motor 342, a fourth brake actuator 344, and a fourth encoder connector 346 that is configured to mate with a fourth position encoder (not shown). FIG. 2 also shows a fourth resistor 348 that is configured to electrically interface with the fourth encoder connector 346, the use of which will be described later in this disclosure.

FIG. 2 also depicts a fifth axis 350 of the robotic manipulator 30 including a fifth motor 352, a fifth brake actuator 354, and a fifth encoder connector 356 that is configured to mate with a fifth position encoder (not shown). FIG. 2 also shows a fifth resistor 358 that is configured to electrically interface with the fifth encoder connector 356, the use of which will be described later in this disclosure.

FIG. 2 also depicts a sixth axis 360 of the robotic manipulator 30 including a sixth motor 362, a sixth brake actuator 364, and a sixth encoder connector 366 that is configured to mate with a sixth position encoder (not shown). FIG. 2 also shows a sixth resistor 368 that is configured to electrically interface with the sixth encoder connector 366, the use of which will be described later in this disclosure.

In the robotic manipulator 30 depicted in FIG. 2, each motor has three wires, each brake actuator has two wires, and each position encoder electrical connector has two wires associated therewith. The wires from each of the components associated with each of the axes are included in the multi-conductor electrical cable 32, with each wire connected to a pin in the first multi-pin connector 36.

With continued reference to FIG. 2, the embodiment of the tool 10 is shown as including a plurality of terminals in a second multi-pin connector 122. The second multi-pin connector 122 is configured to mate with the first multi-pin connector 36, such that when the connectors 122, 36 are mated each pin in the first multi-pin connector 36 is electrically connected to the corresponding pin shown immediately to its left in the second multi-pin connector 122 in the schematic diagram of FIG. 2.

In the embodiment of FIG. 2, the first MCA connection port 22 is configured to connect to a first tool connection port 12, the second MCA connection port 24 is configured to connect to a second tool connection port 14, the third MCA connection port 26 is configured to connect to a third tool connection port 16, and the MCA ground connection port 28 is configured to connect to the tool ground connection port 18 to communicate a ground connection through the tool 10 to the robotic manipulator 30.

As depicted in the embodiment of FIG. 2, the tool 10 includes a switching circuit that allows the first MCA connection port 22, the second MCA connection port 24, and the third MCA connection port 26 to be selectively connected to the three motor leads associated with any one of the six motors each of which is associated with one of the six axes 310, 320, 330, 340, 350, 360 of the robotic manipulator 30. The switching circuit also allows the first MCA connection port 22, the second MCA connection port 24, and the third MCA connection port 26 to be selectively connected to the brake actuator and to the position encoder electrical connector associated with any one of the six axes 310, 320, 330, 340, 350, 360 of the robotic manipulator 30.

The embodiment of FIG. 2 includes a first switch 102, which is a triple-pole triple throw (3P3T) switch having a first pole, a second pole, and a third pole. The first tool connection port 12 is connected to the common contact of the first pole of the first switch 102, the second tool connection port 14 is connected to the common contact of the second pole of the first switch 102, and the third tool connection port 16 is connected to the common contact of the third pole of the first switch 102. The three poles of the first switch 102 are ganged so that they operate simultaneously. When the first switch 102 is in a first position the common contact of the first pole of the first switch 102 is in electrical communication with the common contact of the first pole of a second switch 104, which is a triple-pole double throw (3PDT) switch. When the first switch 102 is in the first position the common contact of the second pole of the first switch 102 is in electrical communication with the common contact of the second pole of the second switch 104, and the common contact of the third pole of the first switch 102 is in electrical communication with the common contact of the third pole of the second switch 104.

When the first switch 102 is in a second position the common contact of the first pole of the first switch 102 is in electrical communication with the common contact of the first pole of a third switch 106, which is a triple-pole double throw (3PDT) switch. When the first switch 102 is in the second position the common contact of the second pole of the first switch 102 is in electrical communication with the common contact of the second pole of the third switch 106, and the common contact of the third pole of the first switch 102 is in electrical communication with the common contact of the third pole of the third switch 106.

When the first switch 102 is in a third position the common contact of the first pole of the first switch 102 is in electrical communication with the common contact of the first pole of a fourth switch 108, which is a triple-pole double throw (3PDT) switch. When the first switch 102 is in the third position the common contact of the second pole of the first switch 102 is in electrical communication with the common contact of the second pole of the fourth switch 108, and the common contact of the third pole of the first switch 102 is in electrical communication with the common contact of the third pole of the fourth switch 108.

With continued reference to FIG. 2, the three poles of the second switch 104 are ganged so that they operate simultaneously. When the second switch 104 is in a first position the common contact of the first pole of the second switch 104 is in electrical communication with the common contact of the first pole of a fifth switch 110, which is a triple-pole double throw (3PDT) switch. When the second switch 104 is in the first position the common contact of the second pole of the second switch 104 is in electrical communication with the common contact of the second pole of the fifth switch 110, and the common contact of the third pole of the second switch 104 is in electrical communication with the common contact of the third pole of the fifth switch 110.

When the second switch 104 is in a second position the common contact of the first pole of the second switch 104 is in electrical communication with the common contact of the first pole of a sixth switch 112, which is a triple-pole double throw (3PDT) switch. When the second switch 104 is in the second position the common contact of the second pole of the second switch 104 is in electrical communication with the common contact of the second pole of the sixth switch 112, and the common contact of the third pole of the second switch 104 is in electrical communication with the common contact of the third pole of the sixth switch 112.

With continued reference to FIG. 2, the three poles of the third switch 106 are ganged so that they operate simultaneously. When the third switch 106 is in a first position the common contact of the first pole of the third switch 106 is in electrical communication with the common contact of the first pole of a seventh switch 114, which is a triple-pole double throw (3PDT) switch. When the third switch 106 is in the first position the common contact of the second pole of the third switch 106 is in electrical communication with the common contact of the second pole of the seventh switch 114, and the common contact of the third pole of the third switch 106 is in electrical communication with the common contact of the third pole of the seventh switch 114.

When the third switch 106 is in a second position the common contact of the first pole of the third switch 106 is in electrical communication with the common contact of the first pole of an eighth switch 116, which is a triple-pole double throw (3PDT) switch. When the third switch 106 is in the second position the common contact of the second pole of the third switch 106 is in electrical communication with the common contact of the second pole of the eighth switch 116, and the common contact of the third pole of the third switch 106 is in electrical communication with the common contact of the third pole of the eighth switch 116.

With continued reference to FIG. 2, the three poles of the fourth switch 108 are ganged so that they operate simultaneously. When the fourth switch 108 is in a first position the common contact of the first pole of the fourth switch 108 is in electrical communication with the common contact of the first pole of a ninth switch 118, which is a triple-pole double throw (3PDT) switch. When the fourth switch 108 is in the first position the common contact of the second pole of the fourth switch 108 is in electrical communication with the common contact of the second pole of the ninth switch 118, and the common contact of the third pole of the fourth switch 108 is in electrical communication with the common contact of the third pole of the ninth switch 118.

When the fourth switch 108 is in a second position the common contact of the first pole of the fourth switch 108 is in electrical communication with the common contact of the first pole of a tenth switch 120, which is a triple-pole double throw (3PDT) switch. When the fourth switch 108 is in the second position the common contact of the second pole of the fourth switch 108 is in electrical communication with the common contact of the second pole of the tenth switch 120, and the common contact of the third pole of the fourth switch 108 is in electrical communication with the common contact of the third pole of the tenth switch 120.

With continued reference to FIG. 2, when the first multi-pin connector 36 is mated to the second multi-pin connector 122, the three output contacts of the fifth switch 110 that are in electrical communication with the three common contacts of the fifth switch 110 when the fifth switch 110 is in its first position are connected to the three wires leading to the first motor 312, and the three output contacts of the fifth switch 110 that are in electrical communication with the three common contacts of the fifth switch 110 when the fifth switch 110 is in its second position are connected to the first brake actuator 314 and the first encoder connector 316.

With continued reference to FIG. 2, when the first multi-pin connector 36 is mated to the second multi-pin connector 122, the three output contacts of the sixth switch 112 that are in electrical communication with the three common contacts of the sixth switch 112 when the sixth switch 112 is in its first position are connected to the three wires leading to the second motor 322, and the three output contacts of the sixth switch 112 that are in electrical communication with the three common contacts of the sixth switch 112 when the sixth switch 112 is in its second position are connected to the second brake actuator 324 and the second encoder connector 326.

With continued reference to FIG. 2, when the first multi-pin connector 36 is mated to the second multi-pin connector 122, the three output contacts of the seventh switch 114 that are in electrical communication with the three common contacts of the seventh switch 114 when the seventh switch 114 is in its first position are connected to the three wires leading to the third motor 332, and the three output contacts of the seventh switch 114 that are in electrical communication with the three common contacts of the seventh switch 114 when the seventh switch 114 is in its second position are connected to the third brake actuator 334 and the third encoder connector 336.

With continued reference to FIG. 2, when the first multi-pin connector 36 is mated to the second multi-pin connector 122, the three output contacts of the eighth switch 116 that are in electrical communication with the three common contacts of the eighth switch 116 when the eighth switch 116 is in its first position are connected to the three wires leading to the fourth motor 342, and the three output contacts of the eighth switch 116 that are in electrical communication with the three common contacts of the eighth switch 116 when the eighth switch 116 is in its second position are connected to the fourth brake actuator 344 and the fourth encoder connector 346.

With continued reference to FIG. 2, when the first multi-pin connector 36 is mated to the second multi-pin connector 122, the three output contacts of the ninth switch 118 that are in electrical communication with the three common contacts of the ninth switch 118 when the ninth switch 118 is in its first position are connected to the three wires leading to the fifth motor 352, and the three output contacts of the ninth switch 118 that are in electrical communication with the three common contacts of the ninth switch 118 when the ninth switch 118 is in its second position are connected to the fifth brake actuator 354 and the fifth encoder connector 356.

With continued reference to FIG. 2, when the first multi-pin connector 36 is mated to the second multi-pin connector 122, the three output contacts of the tenth switch 120 that are in electrical communication with the three common contacts of the tenth switch 120 when the tenth switch 120 is in its first position are connected to the three wires leading to the sixth motor 362, and the three output contacts of the tenth switch 120 that are in electrical communication with the three common contacts of the tenth switch 120 when the tenth switch 120 is in its second position are connected to the sixth brake actuator 364 and the sixth encoder connector 366.

The motor circuit analyzer 20 has a plurality of MCA connection ports 22, 24, 26, 28, and is configured to measure resistance, impedance, inductance, phase angle, dissipation factor, capacitance, and/or insulation resistance of a circuit under test that is electrically connected between two of the plurality of the motor circuit analyzer connection ports. By electrically connecting the MCA connection ports 22, 24, 26, 28 to the tool connection ports 12, 14, 16, 18 and connecting the first multi-pin connector 36 to the mating connector 122 on the tool 10, the motor circuit analyzer 20 can be electrically connected to the robotic manipulator 30. Degradation in a motor winding, in an electrically actuated brake, or in wiring leading to a motor winding or to an electrically actuated brake can in general be readily detected using the motor circuit analyzer 20. A position encoder as used in a robotic manipulator 30 may not present an electrical characteristic at its connection terminals that would lend itself to testing by the motor circuit analyzer 20. Replacing the position encoder with a fixed resistor allows the motor circuit analyzer 20 to provide diagnostic testing of the wiring leading to the position encoder, thereby enabling detection of open circuit, short circuit, and leakage to ground conditions in the encoder wiring. As shown in FIG. 2, each axis 310, 320, 330, 340, 350, 360 of the robotic manipulator 30 can have a fixed resistor connected to its respective encoder connector. For example, the position encoder associated with axis 310 can be unplugged from the first encoder connector 316, and the first resistor 318 plugged into the first encoder connector 316. With the switches 102, 104, 110 set to appropriate positions the resistance across the first encoder connector 316 can be measured between the second tool connection port 14 and the third tool connection port 16. A deviation of the measured value from the expected resistance of the first resistor 318 may be indicative of a fault condition in the wiring associated with the first encoder connector 316. Similarly, resistors can be connected to the encoder connectors associated with the other axes as shown in FIG. 2: the second resistor 328 to the second encoder connector 326, the third resistor 338 to the third encoder connector 336, the fourth resistor 348 to the fourth encoder connector 346, the fifth resistor 358 to the fifth encoder connector 356, and the sixth resistor 368 to the sixth encoder connector 366.

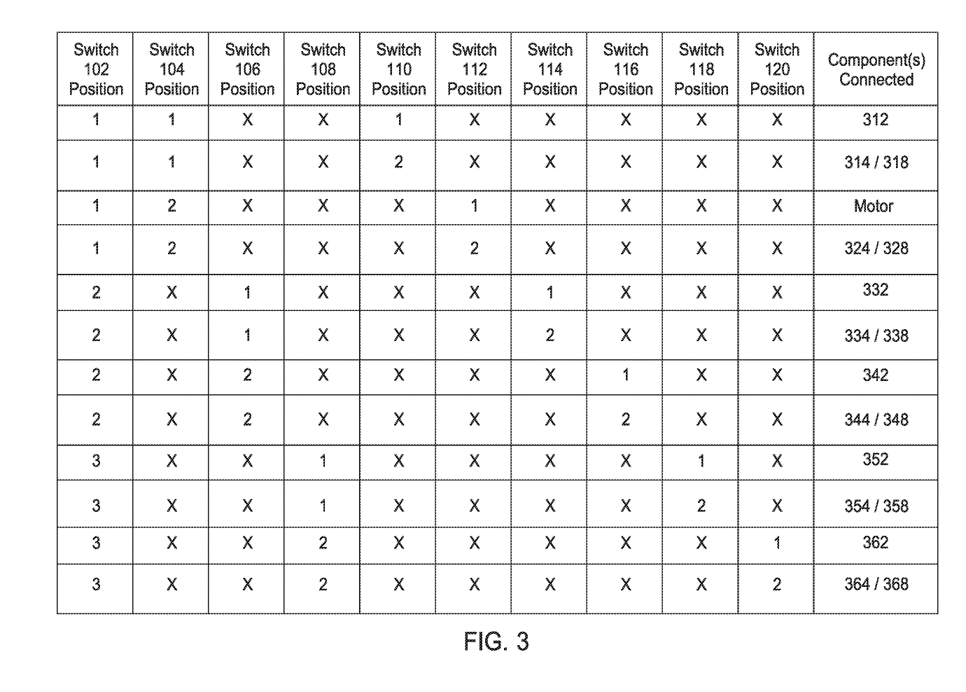

FIG. 3 is a truth table relating the positions of each switch 102, 104, 106, 108, 110, 112, 114, 116, 118, 120 of FIG. 2 to the component in the robotic manipulator 30 that is electrically connected to the tool connection ports 14, 16, 18. As described above, the first switch 102 is a triple throw switch; accordingly there are three possible positions, identified in the leftmost column of FIG. 3 as “1”, “2”, and “3”, for the first switch 102. Each of the remaining switches 104, 106, 108, 110, 112, 114, 116, 118, 120 is described as a double throw switch; accordingly each of the remaining switches 104, 106, 108, 110, 112, 114, 116, 118, 120 has two possible positions, identified as “1” and “2” in FIG. 3. In FIG. 3, an “X” in the table represents a “Don't Care” condition, meaning that the indicated component in the rightmost column of the table is electrically connected to the tool connection ports 14, 16, 18 regardless of the switch position of a switch having an “X” in the table row corresponding to the indicated component. For example, referring to the first row in the table of FIG. 3, when the first switch 102 is in its first position, the second switch 104 is in its first position, and the fifth switch 110 is in its first position, each of the three wires connected to the first motor 312 is electrically connected to one of the three tool connection ports 12, 14, 16, regardless of the position of the switches 106, 108, 112, 114, 116, 118, and 120. From the second row in the table of FIG. 3, when the first switch 102 is in its first position, the second switch 104 is in its first position, and the fifth switch 110 is in its second position, the first brake actuator 314 and the first resistor 318 are electrically connected to the tool connection ports 12, 14, 16, with one brake actuator wire and one resistor wire connected in common, regardless of the position of the switches 106, 108, 112, 114, 116, 118, and 120.

Referring to of FIG. 2 and FIG. 3, the function of the switches can be summarized as follows. The first switch 102 selects among a plurality of pairs of axes. In its first position, the first switch 102 allows connection to components associated with the first axis 310 and the second axis 320; in its second position, the first switch 102 allows connection to components associated with the third axis 330 and the fourth axis 340; and in its third position, the first switch 102 allows connection to components associated with the fifth axis 350 and the sixth axis 360. Each of the switches 104, 106, and 108 each allows for selection of one or the other of the pair of axes corresponding to the first, second, and third positions respectively of the first switch 102. For example, with the first switch 102 in its first position, the second switch 104 allows connection to the first axis 310 for a first position of the second switch 104 and to the second axis 320 for a second position of the second switch 104. Each of the switches 110, 112, 114, 116, 118, and 120 has a first position in which the motor corresponding to the selected axis is connected to the too connection ports 12, 14, 16, and a second position in which the brake actuator and the encoder connector corresponding to the selected axis are connected to the tool connection ports 12, 14, 16.

It will be appreciated that the interface tool 10 depicted in FIG. 2 can be implemented using different switch contact variations as alternatives to the embodiment of FIG. 2. As a non-limiting example, the switches 102, 104, 106, and 108 could be replaced by a single triple-pole six-position switch. Other switch configurations may be used without departing from the spirit or scope of the disclosure. By way of non-limiting example, the switches 102, 104, 106, 108, 110, 112, 114, 116, 118, and 120 may be manually operated using an actuation means including but not limited to a rotating knob, a toggle, a slide, or combinations thereof.

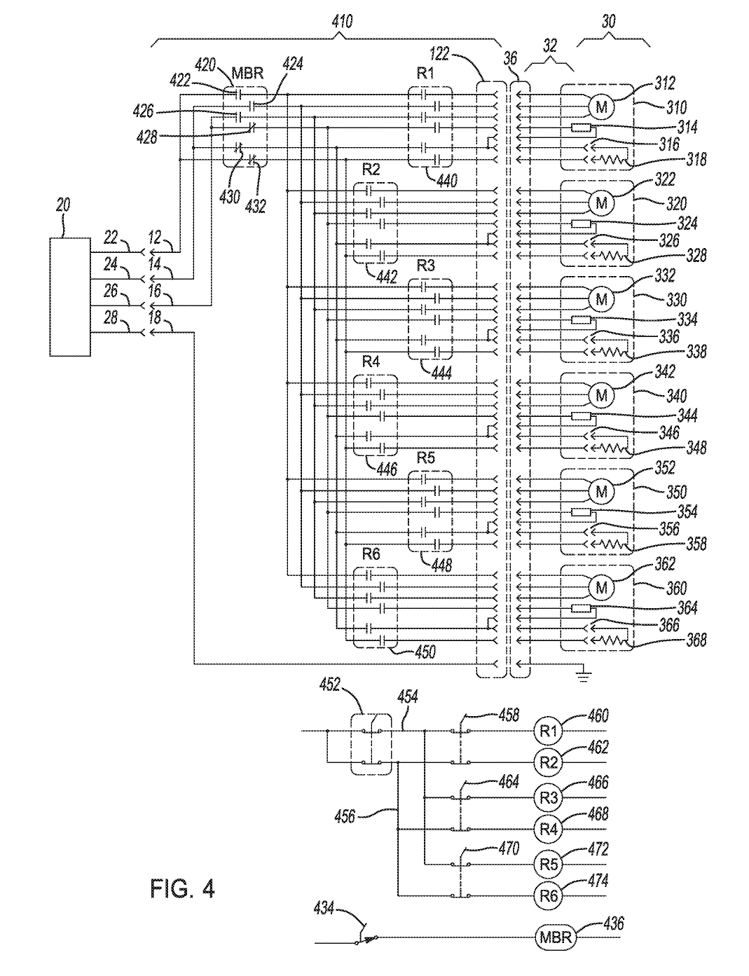

FIG. 4 is a depiction of an alternative embodiment of an interface tool 410 utilizing relay logic in the switching section. With reference to FIG. 4, the first tool connection port 12 is electrically connected to a normally open relay contact 422 and to a normally closed relay contact 432. The second tool connection port 14 is electrically connected to a normally open relay contact 424 and to a normally closed relay contact 430. The third tool connection port 16 is electrically connected to a normally open relay contact 426 and to a normally closed relay contact 428. Relay contacts 422, 424, 426, 428, 430, and 432 are shown in a first contact group 420, labeled MBR. The relay contacts in the first group 420 are controlled by the first relay coil 436. The first relay coil 436 is controlled by selector switch 434. When selector switch 434 is open, the first relay coil 436 is de-energized, contacts 422, 424, and 426 are open, and contacts 428, 430, and 432 are closed. In this state, signals from a selected brake actuator and encoder connector circuit of the robotic manipulator 30 can be conducted to the tool connection ports 12, 14, 16. When selector switch 434 is closed, the first relay coil 436 is energized, contacts 422, 424, and 426 are closed, and contacts 428, 430, and 432 are open. In this state, signals from a selected motor circuit of the robotic manipulator 30 can be conducted to the tool connection ports 12, 14, 16, with the motor circuit selected by the state of the relay contacts in a second group 440, a third group 442, a fourth group 444, a fifth group 446, a sixth group 448, and a seventh group 450.

With continued reference to FIG. 4, the second group 440 of relay contacts is depicted with one side of each contact in the second group 440 connected to a relay contact in the first group 420 and the other side of each contact in the second group 440 connected to a component in the first axis 310 of the robotic manipulator 30. The third group 442 of relay contacts is depicted with one side of each contact in the third group 442 connected to a relay contact in the first group 420 and the other side of each contact in the third group 442 connected to a component in the second axis 320 of the robotic manipulator 30. The fourth group 444 of relay contacts is depicted with one side of each contact in the fourth group 444 connected to a relay contact in the first group 420 and the other side of each contact in the fourth group 444 connected to a component in the third axis 330 of the robotic manipulator 30. The fifth group 446 of relay contacts is depicted with one side of each contact in the fifth group 446 connected to a relay contact in the first group 420 and the other side of each contact in the fifth group 446 connected to a component in the fourth axis 340 of the robotic manipulator 30. The sixth group 448 of relay contacts is depicted with one side of each contact in the sixth group 448 connected to a relay contact in the first group 420 and the other side of each contact in the sixth group 448 connected to a component in the fifth axis 350 of the robotic manipulator 30. The seventh group 450 of relay contacts is depicted with one side of each contact in the seventh group 450 connected to a relay contact in the first group 420 and the other side of each contact in the seventh group 450 connected to a component in the sixth axis 360 of the robotic manipulator 30.

With continued reference to FIG. 4, each of the relay contacts in each of the second group 440, the third group 442, the fourth group 444, the fifth group 446, the sixth group 448, and the seventh group 450 are shown as normally open contacts. The relay contacts in the second group 440 are closed when a second relay coil 460 is energized. The relay contacts in the third group 442 are closed when a third relay coil 462 is energized. The relay contacts in the fourth group 444 are closed when a fourth relay coil 466 is energized. The relay contacts in the fifth group 446 are closed when a fifth relay coil 468 is energized. The relay contacts in, the sixth group 448 are closed when relay coil 472 is energized. The relay contacts in the seventh group 450 are closed when a seventh relay coil 474 is energized.

Control of the energization of the relay coils 460, 462, 466, 468, 472, and 474 is achieved by the selector switches 452, 458, 464, and 470. For example, when the selector switches 452, 458, 464, and 470 are positioned such that the second relay coil 460 is energized and relay coils 462, 466, 468, 472, and 474 are de-energized, each of the relay contacts in the second group 440 are closed and each of the relay contacts in the third group 442, the fourth group 444, the fifth group 446, the sixth group 448, and the seventh group 450 are open. In this state the components associated with the first axis 310 of the robotic manipulator 30 are electrically connected with the right side of the relay contacts shown in the first group 420. In a first position of the switch 434 each of the three wires connected to the first motor 312 is electrically connected to one of the tool connection ports 12, 14, and 16. In a second position of the switch 434 the first brake actuator 314 and the first resistor 318 are electrically connected to the tool connection ports 12, 14, 16, with one brake actuator wire and one resistor wire connected in common. Other combinations of positions of selector switches 452, 458, 464, and 470 will allow connection of components (motor, brake, and encoder connector) associated with other axes 320, 330, 340, 350, 360 to the tool connection ports 12, 14, 16.

The tool and method disclosed herein facilitate measurement of one or more electrical properties associated with components in the robotic manipulator 30. The measured value of a measured electrical property may be compared to a predetermined range to determine if action is warranted. The predetermined range may be an absolute range for the electrical property being considered. Alternatively, the predetermined range may be based on the value of the same electrical property previously measured at an earlier time on the same component, in which case the magnitude and/or direction of change in the measured property may be indicative of degradation of the component or of its associated wiring. The tool 10, 410 and method disclosed herein facilitate detection of degraded components within the robotic manipulator 30, so that components identified as being degraded may be serviced before unplanned downtime occurs as a result of failure of the degraded components.

The examples presented above depict the motor circuit analyzer 20 having three MCA connection ports 22, 24, 26 connected to the tool 10, with the tool 10 having a switching section that allows the three MCA connection ports 22, 24, 26 to be selectively connected to three conductors leading to the robotic manipulator 30. It will be appreciated that an alternative embodiment of the tool 10, in which two motor circuit analyzer connection ports of the motor circuit analyzer 20 are selectively connected to two conductors leading to the robotic manipulator 30, is within the scope and spirit of the present disclosure.

While the foregoing description describes switches having switch contacts that close by physically touching one another and open by physically separating from each other, it will be appreciated that other switching means are possible. By way of non-limiting example, solid state switches in which conduction through a semiconductor material is enabled or disabled by a control signal may be a suitable alternative.

While the examples presented relate to a robotic manipulator, the apparatus and method described herein can be applied to other types of electrically operated machines, including but not limited to Computer Numeric Control (CNC) machining centers or servo-operated dispensing systems, without departing from the spirit and scope of the disclosure.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. For purposes of clarity, the same reference numbers are used in the drawings to identify similar elements. As used herein, the phrase at least one of A, B, and C should be construed to mean a logical (A or B or C), using a non-exclusive logical OR. It should be understood that one or more steps within a method may be executed in different order (or concurrently) without altering the principles of the present disclosure.

What is claimed is:

1. A tool for providing an electrical interface between a motor circuit analyzer comprising a plurality of motor circuit analyzer connection ports and an electrically operated machine comprising a plurality of electrical devices and a multi-conductor cable comprising electrical wires configured to electrically connect to the plurality of electrical devices; the tool comprising:
a plurality of tool connection ports, each tool connection port configured to be electrically connected to one of the plurality of motor circuit analyzer connection ports;
a plurality of terminals, each terminal configured to be electrically connected to one of the conductors of the multi-conductor cable; and
a switching section configured to selectively electrically connect a first tool connection port to a first terminal and to selectively electrically connect a second tool connection port to a second terminal.

2. The tool according to claim 1 wherein the plurality of electrical devices comprises a plurality of electric motors.

3. The tool according to claim 1 wherein the plurality of electrical devices comprises a plurality of electrically actuated brakes.

4. The tool according to claim 1 wherein the plurality of electrical devices comprises a plurality of electrically readable position sensors.

5. The tool according to claim 1 wherein the switching section is further configured to selectively electrically connect a third tool connection port to a third terminal.

6. The tool according to claim 1 wherein the motor circuit analyzer is configured to measure resistance, impedance, inductance, phase angle, dissipation factor, capacitance, and/or insulation resistance of a circuit that is electrically connected between two of the plurality of the motor circuit analyzer connection ports.

7. The tool according to claim 1 wherein the multi-conductor cable is terminated in a first multi-pin connector, and wherein the tool includes a second multi-pin connector that is configured to mate with the first multi-pin connector.

8. The tool according to claim 7 wherein each terminal is a pin in the second multi-pin connector.

9. The tool according to claim 1 wherein the switching section comprises a plurality of sets of electrical contacts, wherein each set of contacts can selectively be placed in a closed state in which the contacts in the set of contacts are touching and able to conduct electricity therebetween and in an open state in which the contacts in the set of contacts are separated and unable to conduct electricity therebetween.

10. The tool according to claim 9 wherein at least one of the plurality of sets of electrical contacts is a set of relay contacts whose opening and closing is controlled by current through a relay coil.

11. The tool according to claim 10 wherein the relay coil is configured to control opening and closing of a plurality of sets of electrical contacts.

12. The tool according to claim 9 wherein opening and closing of at least one of the plurality of sets of electrical contacts is controlled by a mechanically operated actuator.

13. A method for using a tool to analyze an electrically operated machine with a motor circuit analyzer comprising a plurality of motor circuit analyzer connection ports, the electrically operated machine comprising a plurality of electrical devices and a multi-conductor cable comprising electrical wires configured to electrically connect to the plurality of electrical devices, the tool comprising:
a plurality of tool connection ports;
a plurality of terminals; and
a switching section comprising a plurality of switches configured to selectively electrically connect a first tool connection port to a first terminal and to selectively electrically connect a second tool connection port to a second terminal;
the method comprising the steps of:
connecting a first tool connection port to a first motor circuit analyzer connection port;
connecting a second tool connection port to a second motor circuit analyzer connection port;
connecting the multi-conductor cable to the plurality of terminals;
configuring the switches in the switching section to electrically connect the first motor circuit analyzer connection port and the second motor circuit analyzer connection port to one of the plurality of electrical devices; and
measuring an electrical property associated with the one of the plurality of electrical devices using the motor circuit analyzer.

14. The method according to claim 13 further comprising the step of comparing the measured value of the electrical property to a predetermined range.

15. The method according to claim 14 wherein the predetermined range is based on a measurement taken at a previous time of the same electrical property associated with the same electrical device.

16. The method according to claim 13 further including the steps of:
disconnecting one of the plurality of electrical devices from the multi-conductor cable; and
connecting a circuit element having a known impedance to the multi-conductor cable in place of the disconnected device.

17. The method according to claim 16 wherein the disconnected device is an electrically readable position sensor.

18. The method according to claim 13 wherein the electrical property is selected from the group consisting of resistance, impedance, inductance, phase angle, dissipation factor, capacitance, and insulation resistance.

19. The method according to claim 13 further including the steps of:
connecting a third tool connection port to a third motor circuit analyzer connection port; and
configuring the switches in the switching section to electrically connect the third motor circuit analyzer connection port to one of the plurality of electrical devices.

20. A tool for providing an electrical interface between a motor circuit analyzer and an electrically operated machine manipulator;
wherein the motor circuit analyzer comprises a plurality of motor circuit analyzer connection ports, wherein the motor circuit analyzer is configured to measure resistance, impedance, inductance, phase angle, dissipation factor, capacitance, and/or insulation resistance of a circuit that is electrically connected between two of the plurality of the motor circuit analyzer connection ports;
wherein the electrically operated machine comprises a plurality of electric motors, a plurality of electrically actuated brakes, a plurality of electrically readable position sensors, and a multi-conductor cable comprising electrical wires configured to electrically connect to the plurality of electric motors, the plurality of electrically actuated brakes, and the plurality of electrically readable position sensors, wherein the multi-conductor cable is terminated in a first multi-pin connector;
the tool comprising:
a plurality of tool connection ports, each tool connection port configured to be electrically connected to one of the plurality of motor circuit analyzer connection ports;
a plurality of terminals, each terminal configured to be electrically connected to one of the conductors of the multi-conductor cable; and
a switching section configured to selectively electrically connect a first tool connection port to a first terminal and to selectively electrically connect a second tool connection port to a second terminal;
wherein the tool includes a second multi-pin connector that is configured to mate with the first multi-pin connector;
wherein each terminal is a pin in the second multi-pin connector; and
wherein the switching section comprises a plurality of sets of electrical contacts, wherein each set of contacts can selectively be placed in a closed state in which the contacts in the set of contacts are touching and able to conduct electricity therebetween and in an open state in which the contacts in the set of contacts are separated and unable to conduct electricity therebetween.
